(19) United States
(12) Patent Application Publication
(10) Pub. No.: US 2026/0282839 A1
(43) Pub. Date: Sep. 17, 2026

(54) METHOD TO CORRECT WAFER PLACEMENT FOR CHANNEL IMPLANT

(71) Applicant: Axcelis Technologies, Inc., Beverly, MA (US)

(72) Inventors: Mandar Deshpande, Phoenix, AZ (US); Vincent Szeto, Newton, MA (US); Steve Drummond, Merrimac, MA (US)

(21) Appl. No.: 19/562,405

(22) Filed: Mar. 10, 2026

Related U.S. Application Data
(60) Provisional application No. 63/772,269, filed on Mar. 14, 2025.

(51) Int. Cl. H10P 72/76; H01J 37/20; H01J 37/317; H10P 72/00; H10P 72/50

(52) U.S. Cl. CPC H10P 72/7618; H01J 37/20; H01J 37/3171; H10P 72/0606; H10P 72/53; H01J 2237/20214; H01J 2237/20285

(57) ABSTRACT

An ion implantation system includes a chuck configured to support a workpiece on a support surface. The chuck is configured to rotate about a twist axis, which is orthogonal to the support surface. The system further includes a robot arm having an end effector configured to transport the workpiece to and from the support surface of the chuck, with the chuck being in a first position. The system further includes a camera configured to capture one or more images of the workpiece disposed on the support surface of the chuck in the first position. The system further includes a controller configured to send instructions to the chuck to rotate about the twist axis or to the robot arm to move the workpiece to correct the orientation of the workpiece for ion implantation based on the images captured by the camera.

### CROSS-REFERENCE TO RELATED APPLICATIONS

This application claims priority to the provisional patent application filed Mar. 14, 2025 and assigned U.S. App. No. 63/772,269, the disclosure of which is hereby incorporated by reference.

### FIELD OF THE DISCLOSURE

This disclosure relates to ion implantation systems and, more particularly, to wafer handling within an ion implantation system.

### BACKGROUND OF THE DISCLOSURE

In the manufacture of semiconductor devices, ion implantation is used to dope semiconductors with impurities. Ion implantation systems are often used to implant a workpiece, such as a semiconductor wafer, with ions from an ion beam to produce n-type or p-type material doping or to form passivation layers during fabrication of an integrated circuit. Such beam treatment can selectively implant the wafers with impurities of a specified dopant material, at a predetermined energy level, and in controlled concentration to produce a semiconductor material during fabrication of an integrated circuit. When used for doping semiconductor wafers, the ion implantation system injects a selected ion species into the workpiece to produce the desired extrinsic material. Implanting ions generated from source materials such as antimony, arsenic, or phosphorus, for example, results in an “n-type” extrinsic material workpiece, whereas a “p-type” extrinsic material workpiece often results from ions generated with source materials such as boron, gallium, or indium.

A typical ion implanter includes an ion source, an ion extraction device, a mass analysis device, a beam transport device, and a process chamber. The ion source generates ions of desired atomic or molecular dopant species. These ions are extracted from the source by an extraction system, typically a set of electrodes, which energize and direct the flow of ions from the source, forming an ion beam. Desired ions are separated from the ion beam in a mass analysis device, typically a magnetic dipole performing mass dispersion or separation of the extracted ion beam. The beam transport device, typically a vacuum system containing a series of focusing devices, transports the ion beam to the wafer processing device while maintaining desired properties of the ion beam. Finally, workpieces are transferred in to and out of the process chamber via a workpiece handling system, which may include one or more robotic arms, for placing a workpiece to be treated in front of the ion beam and removing treated workpieces from the ion implanter.

The orientation of the ion beam relative to the lattice structure of a wafer (i.e., twist angle and centering of the wafer) can affect channeling. For example, aligning the ion beam with the lattice structure can cause few ions to encounter the structure, such that the ions are implanted relatively deeply into the substrate. Alternatively, mis-aligning the ion beam with the lattice structure can cause some of the ions to encounter some of the lattice structure and may be blocked, slowed down or reflected and reduce the depth of channeling. In either instance, improper alignment can lead to undesired degrees of channeling (e.g., too little or too much) and can impact the implant distribution at the edge of the wafer. Additionally, the deviations from the nominal lattice orientation and the dimensions of features formed upon the wafer can affect shadowing, and adversely impact the implantation process and resulting devices.

### BRIEF SUMMARY OF THE DISCLOSURE

An embodiment of the present disclosure provides an ion implantation system. The system may comprise a chuck configured to support a workpiece on a support surface. The chuck may be configured to rotate about a twist axis. The twist axis may be orthogonal to the support surface. The chuck may be further configured to move between a first position and a second position. The system may further comprise a robot arm having an end effector configured to transport the workpiece to and from the support surface of the chuck in the first position. The system may further comprise a camera configured to capture one or more images of the workpiece disposed on the support surface of the chuck in the first position. The system may further comprise a controller in electronic communication with the camera, the chuck, and the robot arm. The controller may be configured to: receive the one or more images of the workpiece from the camera; determine an orientation of the workpiece based on the one or more images of the workpiece; determine an error correction based on the orientation of the workpiece; send instructions to the robot arm to remove the workpiece from the support surface of the chuck; send instructions to the chuck to rotate about the twist axis or send instructions to the robot arm to move the workpiece according to the error correction; and send instructions to the robot arm to dispose the workpiece onto the support surface of the chuck to correct the orientation of the workpiece.

In some embodiments, the system may further comprise an ion source configured to emit an ion beam onto the workpiece disposed on the support surface of the chuck in the second position. The controller may be in electronic communication with the ion source. The controller may be further configured to: send instructions to the chuck to move from the first position to the second position after correcting the orientation of the workpiece; and send instructions to the ion source to emit the ion beam onto the workpiece.

In some embodiments, the ion beam may be configured to perform channel implantation in the workpiece.

In some embodiments, the orientation of the workpiece may include a centering of workpiece on the support surface of the chuck and a twist angle of the workpiece relative to the twist axis of the chuck. The controller may be configured to determine the centering of the workpiece by comparing an outline of the workpiece in the one or more images to a reference outline. The controller may be configured to determine the twist angle of the workpiece by comparing a notch or flat of the workpiece in the one or more images to a reference fiducial. The error correction may include a rotation of the chuck along the twist axis to compensate for the twist angle of the workpiece. The rotation of the chuck along the twist axis may compensate for the twist angle of the workpiece by rotating to a predetermined angle set by inspection of the workpiece at an upstream inspection tool, such as an x-ray diffraction (XRD) tool. The error correction may further include a movement of the end effector of the robot arm to compensate for the centering of the workpiece.

In some embodiments, the controller may be further configured to: receive one or more images of the workpiece after the robot arm disposes the workpiece onto the support surface of the chuck; and verify the corrected orientation of the workpiece based on the one or more images of the workpiece.

In some embodiments, the chuck may include a first motor configured to rotate the chuck along the twist axis and a second motor configured to move the chuck from the first position to the second position.

Another embodiment of the present disclosure provides an ion implantation method. The method may comprise: capturing, with a camera, one or more images of a workpiece disposed on a support surface of a chuck; determining, with a controller, an orientation of the workpiece based on the one or more images of the workpiece received from the camera; determining, with the controller, an error correction based on the orientation of the workpiece; removing, with a robot arm, the workpiece from the support surface of the chuck; rotating the chuck along a twist axis or moving the robot arm according to the error correction; and disposing, with the robot arm, the workpiece onto the support surface of the chuck to correct the orientation of the workpiece.

In some embodiments, the method may further comprise moving the chuck from a first position to a second position. In the first position, the workpiece disposed on the support surface of the chuck may be aligned with the camera, and in the second position, the workpiece disposed on the support surface of the chuck may be aligned with an ion beam. The method may further comprise emitting, with an ion source, the ion beam onto the workpiece. The ion beam may be configured to perform channel implantation in the workpiece.

In some embodiments, the orientation of the workpiece may include a centering of the workpiece on the support surface of the chuck and a twist angle of the workpiece relative to the twist axis of the chuck. The error correction may include a rotation of the chuck along the twist axis to compensate for the twist angle of the workpiece. The rotation of the chuck along the twist axis may compensate for the twist angle of the workpiece by rotating to a predetermined angle set by inspection of the workpiece at an upstream inspection tool, such as, for example, an x-ray diffraction (XRD) tool. The error correction may further include a movement of the end effector of the robot arm to compensate for the centering of the workpiece.

In some embodiments, determining, with the controller, the orientation of the workpiece based on the one or more images of the workpiece received from the camera may comprise: determining the centering of the workpiece by comparing an outline of the workpiece in the one or more images to a reference outline; and/or determining the twist angle of the workpiece by comparing a notch or flat of the workpiece in the one or more images to a reference fiducial.

In some embodiments, the method may further comprise: capturing, with the camera, one or more additional images of the workpiece after the robot arm disposes the workpiece onto the support surface of the chuck; and determining, with the controller, the orientation of the workpiece based on the one or more additional images of the workpiece to verify that the workpiece is in the correct orientation.

### DESCRIPTION OF THE DRAWINGS

For a fuller understanding of the nature and objects of the disclosure, reference should be made to the following detailed description taken in conjunction with the accompanying drawings, in which:

FIG. 1 is a diagram of a process chamber of a system according to an embodiment of the present disclosure, in which a chuck is provided in a first position for receiving a workpiece from a robot arm;

FIG. 2 is a diagram of the process chamber of FIG. 1, in which a camera captures at least one image of the workpiece supported by the chuck;

FIG. 3 is a diagram of the process chamber of FIG. 1, in which the chuck is provided in a second position for ion implantation;

FIG. 4 is an exemplary illustration of an image of the workpiece having both twist and centering error;

FIG. 5 is an exemplary illustration of an image of the workpiece having corrected twist and centering;

FIG. 6 is a diagram of a system according to an embodiment of the present disclosure;

FIG. 7 is a method according to an embodiment of the present disclosure; and

FIG. 8 is a method according to another embodiment of the present disclosure.

### DETAILED DESCRIPTION OF THE DISCLOSURE

Although claimed subject matter will be described in terms of certain embodiments, other embodiments, including embodiments that do not provide all of the benefits and features set forth herein, are also within the scope of this disclosure. Various structural, logical, process step, and electronic changes may be made without departing from the scope of the disclosure. Accordingly, the scope of the disclosure is defined only by reference to the appended claims.

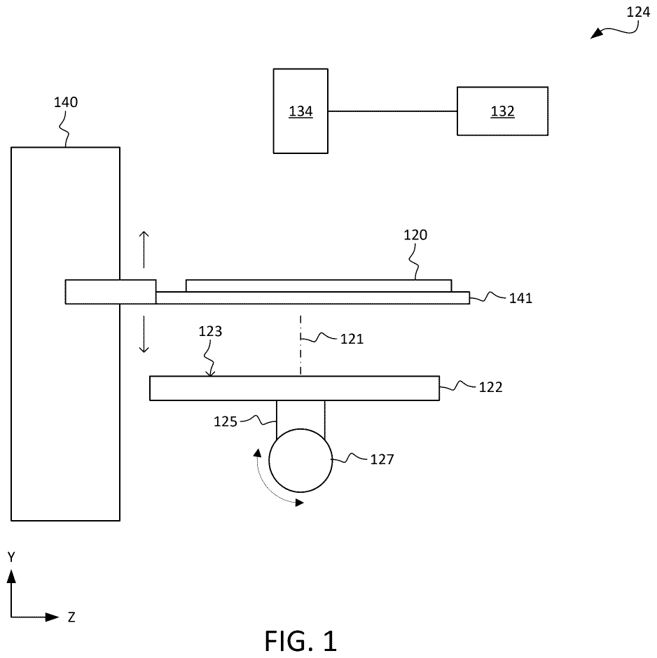

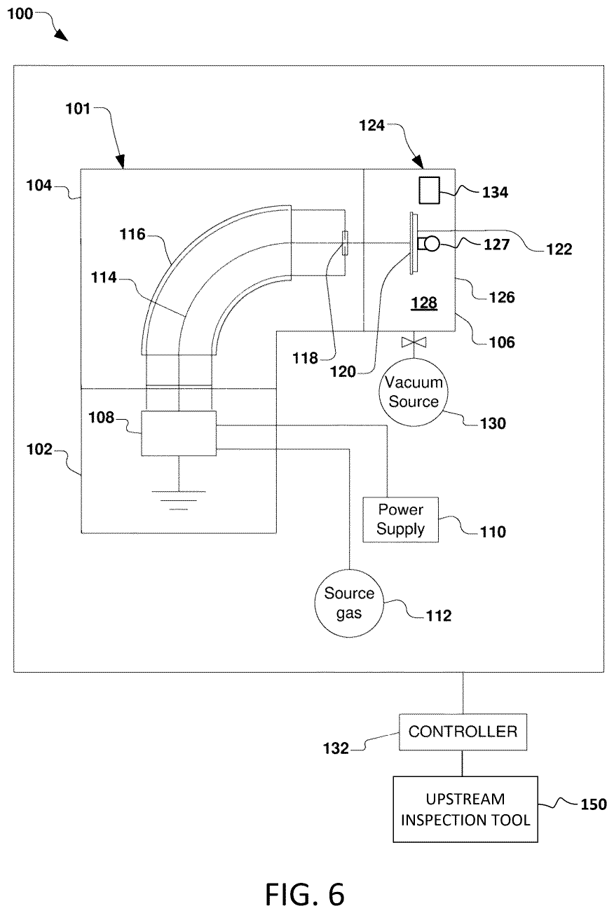

FIGS. 1-3 illustrate exemplary elements within a process chamber 124 of a system 100 of the present disclosure (shown later in FIG. 6), which may allow for correction of wafer placement and alignment for ion implantation. In particular, the elements may provide a high-resolution vision-based system capable of accurately measuring wafer angle and position shift after transfer through atmospheric to vacuum wafer transfer system, and to be able to compensate for the shift prior to placing the wafer on an electrostatic chuck or mechanical clamp.

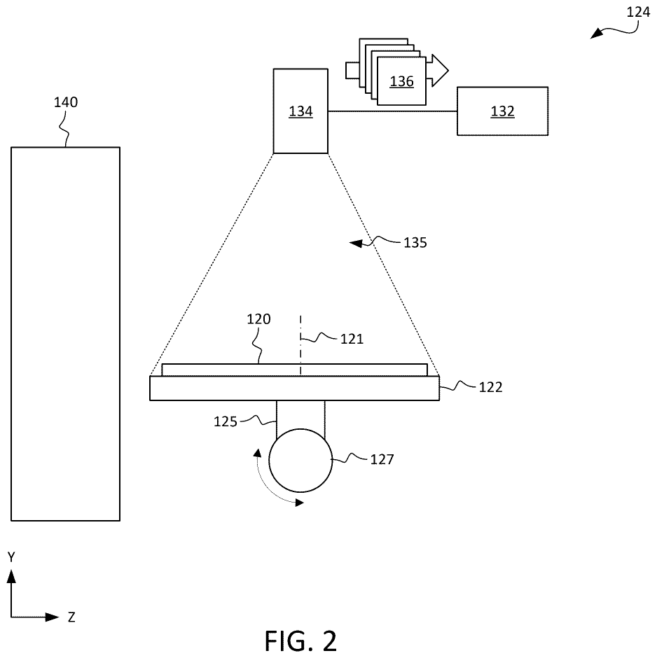

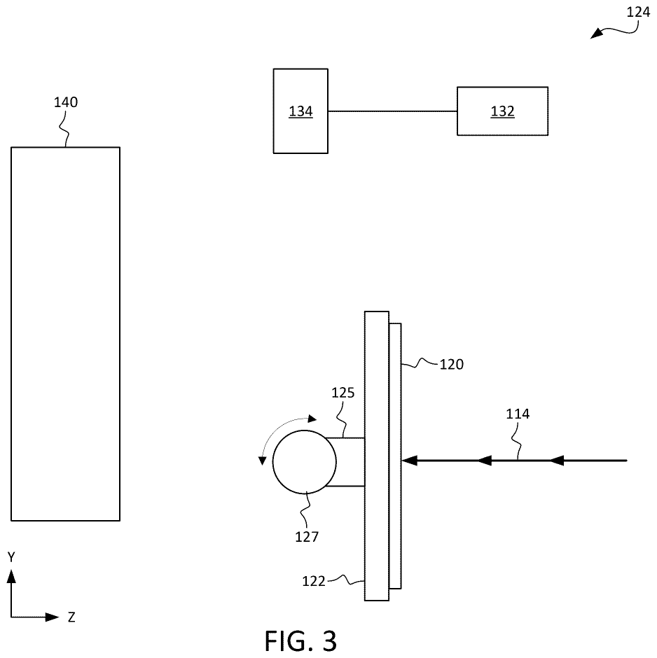

A chuck 122 may be configured to support the workpiece 120 on a support surface 123 of the chuck 122. The chuck 122 may be configured to rotate about a twist axis 121. The twist axis 121 may be orthogonal to the support surface 123. The twist axis 121 may intersect a center point of the workpiece 120 provided on the support surface 123. The twist axis 121 may be provided centrally with respect to the support surface 123 of the chuck 122. The chuck 122 may comprise a first motor 125 configured to rotate the chuck 122 about the twist axis 121. The chuck 122 may be further configured to rotate between a first position (shown in FIGS. 1 and 2) and a second position (shown in FIG. 3). The first position may be a load/unload position, in which the workpiece 120 is loaded/unloaded from the chuck 122. The second position may be an ion implantation position, in which the workpiece 120 is implanted with ions from the ion beam 114 (FIG. 3). The chuck 122 may further comprise a second motor 127 configured to rotate the chuck 122 between the first position and the second position.

A robot arm 140 having an end effector 141 may be configured to transport the workpiece 120 to and from the support surface 123 of the chuck 122 in the first position, as shown in FIG. 1. The robot arm 140 may be provided within the process chamber 124, or the end effector 141 of the robot arm 140 may extend into the process chamber 124 to dispose the workpiece 120 on the support surface 123 and to remove the workpiece 120 from the support surface 123.

A camera 134 may be configured to capture one or more images 136 of the workpiece 120 disposed on the support surface 123 of the chuck 122 in the first position, as shown in FIG. 2. The camera 134 may be provided within the process chamber 124, or the camera 134 may be provided such that the workpiece 120 disposed on the support surface 123 is within a field of view 135 of the camera 134 through an aperture (not shown) from outside of the process chamber 124 (i.e., a transparent viewport a vacuum chamber defining the process chamber 124). The camera 134 may be provided in an orientation close to normal to the surface of the workpiece 120, with the camera 134 having a field of view of the full surface of the workpiece 120.

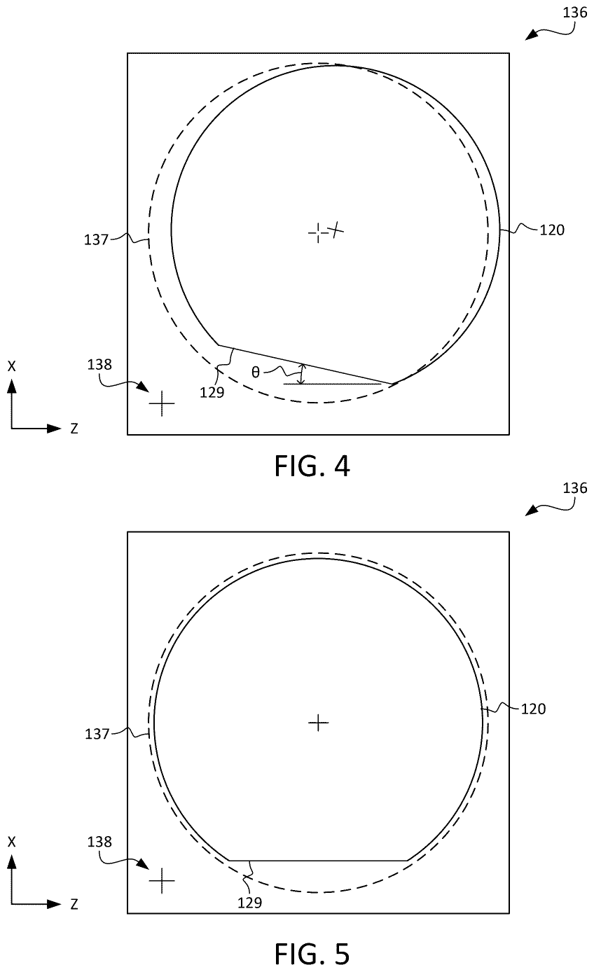

A controller 132 may be configured to receive the one or more images 136 of the workpiece 120 from the camera 134. For example, the controller 132 may be configured to execute image acquisition software and image recognition software in conjunction with the camera 134 to receive and process the one or more image 135 of the workpiece 120 from the camera 134. In some embodiments, the camera 134 may be continuously capturing images 136 of the workpiece 120, and the controller 132 may continuously receive the one or more images of the workpiece 120 from the camera 134. Alternatively, the camera 134 may capture the one or more images 136 of the workpiece 120 after identifying that the workpiece 120 is within the field of view 135 of the camera 134. The controller 132 may be configured to determine an orientation of the workpiece 120 based on the one or more images 136 of the workpiece 120. For example, the orientation of the workpiece 120 may include a centering of the workpiece 120 on the support surface 123 of the chuck 122 and a twist angle θ of the workpiece 120 relative to the twist axis 121 of the chuck 122. The controller 132 may be configured to determine the centering of the workpiece 120 may comparing an outline of the workpiece 120 in the one or more images 136 to a reference outline 137, as shown in FIG. 4. For example, the workpiece 120 may be a standard semiconductor wafer substrate having a diameter of 100 mm, 150 mm, 200 mm, 300 mm, or other nominal diameter, made of silicon, glass, silicon carbide, or other materials. The reference outline 137 may correspond to the nominal diameter of the workpiece 120 known by the controller 132. The workpiece 120 may have a predefined flat or notch 129 determined by its crystal orientation, as specified in industry standards. The controller 132 may be configured to determine the twist angle θ of the workpiece 120 by comparing the notch 129 or flat of the workpiece 120 in the one or more images 136 to a reference fiducial 138, as shown in FIG. 4. The reference fiducial 138 may be provided on the support surface 123 of the chuck 122 or on the end effector 141 of the robot arm 140, depending on which features are visible in the one or more images 136 of the workpiece 120. The controller 132 may be configured to overlay the reference outline 137 and the reference fiducial 138 onto each image 136 of the workpiece 120 to determine the orientation of the workpiece 120. Although the workpiece 120 is described in the examples above as being circular, the controller 134 may be configured to determine an orientation of a workpiece 120 that is square, rectangular, or other shapes in a similar manner to what is described above.

The controller 132 may be configured to determine an error correction based on the orientation of the workpiece 120. For example, the error correction may include a rotation of the chuck 122 along the twist axis 121 to compensate for an error in the twist angle θ of the workpiece 120 and/or the error correction may include a movement of the end effector 141 of the robot arm 140 to compensate for an error in the centering of the workpiece 120. In some embodiments, the error correction may include a rotation of the chuck 122 along the twist axis 121 to align the notch 129 or flat of the workpiece 120 with the reference fiducial 138 (i.e., θ=0). Alternatively, the error correction may include a rotation of the chuck 122 along the twist axis 121 to provide the notch 129 or flat of the workpiece 120 at a predetermined angle with the reference fiducial 138 (i.e., θ≠0). The predetermined angle may be set based on inspection of the workpiece 120 at an earlier stage (i.e., upstream) in the system 100. For example, an x-ray diffraction (XRD) tool may be used to determine the crystalline structure and crystalline orientation of the workpiece 120 at an earlier stage in the system 100, and a separate camera can be used to capture one or more images of the workpiece 120 while under inspection by the XRD tool in order to determine the twist angle θ of the workpiece 120 relative to a fiducial marker of the XRD stage. Accordingly, the error correction may rotate the chuck 122 along the twist axis 121 according to the predetermined angle, such that the workpiece 120 is in the same orientation as when inspected by the XRD tool, which can improve alignment of the workpiece 120 for channel implants. In an instance, the error in the twist angle θ of the workpiece 120 may typically be less than 1 degree. However, the chuck 122 may be configured to rotate along the twist axis 121 to correct an error in the twist angle θ of the workpiece 120 up to 180 degrees.

Once the error correction is determined, the controller 132 may be configured to second instructions to the robot arm 140 to remove the workpiece 120 from the support surface 123 of the chuck 122. The controller 132 may be further configured to second instructions to the chuck 122 to rotate about the twist axis 121 and/or send instructions to the robot arm 140 to move the workpiece 120 according to the error correction. For example, the chuck 122 may rotate about the twist axis 121 according to the same twist angle θ determined according to the orientation of the workpiece 120. Alternatively, the chuck 122 may rotate about the twist axis 121 according to the predetermined angle set during inspection by the XRD tool. The controller 132 may be further configured to send instructions to the robot arm 140 to dispose the workpiece 120 onto the support surface 123 of the chuck 122 to correct the orientation of the workpiece 120. For example, the robot arm 140 may move the end effector 141 to compensate for an offset between the center point of the workpiece 120 determined from the orientation of the workpiece 120 and the center of the support surface 123 of the chuck 122, such that the workpiece 120 has correct centering when placed on the support surface 123. Once the workpiece 120 is disposed on the chuck 122, the chuck 122 may rotate about the twist axis 121 to correct the error in the twist angle of the workpiece 120. For example, the chuck 122 may rotate back to a zero position, such that the workpiece 120 is aligned with a zero-angle position of the chuck 122. Alternatively, the controller 132 may be configured to reset the zero-angle position of the chuck 122 as the current twist angle θ.

The controller 132 may be further configured to verify the corrected orientation of the workpiece 120. For example, the controller 132 may be configured to receive one or more additional images 136 of the workpiece 120 from the camera 134 after the robot arm 140 disposes the workpiece 120 onto the support surface 123 of the chuck 122. Based on the determined orientation of the workpiece 120 in the one or more additional images 136, the controller 132 may be configured to determine that the workpiece 120 is in a correct orientation. For example, as shown in FIG. 5, the outline of the workpiece 120 in the image 136 may be within the reference outline 137 (indicating correct centering of the workpiece 120) and the notch 129 of the workpiece 120 may align with the reference fiducial 138 or may be at a predetermined angle relative to the reference fiducial 138 (indicating correct twist angle of the workpiece 120). If the controller 132 determines that there is still an error in the orientation of the workpiece 120, the controller 132 may determine further error correction(s), and send instructions to the robot arm 140 to remove/replace the workpiece 120 onto the support surface 123 of the chuck with appropriate rotation of the chuck 122 in an iterative process until the images 136 of the workpiece 120 indicate a correct orientation.

Once the controller 132 has verified that the workpiece 120 is in the correct orientation, the controller 132 may be configured to send instructions to the chuck 122 to move from the first position to the second position. In the second position, the support surface 123 of the chuck may be aligned with or otherwise in a path of the ion beam 114 emitted from an ion source, such as ion source 108 in FIG. 6. The instructions sent to the chuck 122 may include the tilt angle of the chuck 122 which defines the second position. The tilt angle may be a predefined angle (e.g., 90 degrees) relative to the first position or may be a predetermined angle set during earlier inspection of the workpiece 120. The tilt angle may be defined such that the surface of the workpiece 120 is orthogonal to the path of the ion beam 114 (which may be parallel to or angled relative to the support surface 123 of the chuck 122) or at an angle such that the ion beam 114 aligns with the crystalline structure and crystalline orientation of the workpiece 120. The workpiece 120 may be held to the support surface 123 of the chuck 122 by electrostatic force, vacuum pressure, or mechanical clamps, so as to remain in the correct orientation with the chuck 122 in the second position. The controller 132 may be configured to send instructions to the ion source 108 to emit the ion beam 114 onto the workpiece 120. For example, the ion beam 114 may be configured to perform channel implantation in the workpiece 120. Based on the corrected orientation of the workpiece 120, verified by the images 136 of the workpiece 120 captured by the camera 134, the ion beam 114 can be aligned with the lattice structure of the workpiece 120 to control implantation depth for consistent channel implantation.

FIG. 6 illustrates an exemplified vacuum system 100 that may implement various apparatus, systems, and methods of the present disclosure. The vacuum system 100 includes an ion implantation system 101, however various other types of vacuum systems are also contemplated, such as plasma processing systems or other semiconductor processing systems. The ion implantation system 101, for example, comprises a terminal 102, a beamline assembly 104, and an end station 106.

Generally speaking, an ion source 108 in the terminal 102 is coupled to a power supply 110, whereby a gas from a gas source 112 (also called a dopant gas) supplied thereto and/or material from a target is ionized into a plurality of ions to form an ion beam 114. The ion beam 114 is directed through a beam-steering apparatus 116 and out an aperture 118 toward the end station 106. In the end station 106, the ion beam 114 bombards a workpiece 120 (e.g., a semiconductor such as a silicon wafer, a display panel, etc.), which is selectively clamped or mounted to a chuck 122 (e.g., an electrostatic chuck). The chuck 122 may be configured to perform the functions of the chuck of the various embodiments described herein. Once embedded into the lattice of the workpiece 120, the implanted ions change the physical and/or chemical properties of the workpiece 120. Because of this, ion implantation is used in semiconductor device fabrication and in metal finishing, as well as various applications in materials science research.

The ion beam 114 of the present disclosure can take any form, such as a pencil or spot beam, a ribbon beam, a scanned beam, or any other form in which ions are directed toward end station 106, and all such forms are contemplated as falling within the scope of the disclosure.

The end station 106 includes a process chamber 124, such as a vacuum chamber 126, wherein a process environment 128 is associated with the process chamber 124. The process chamber 124 may contain the various elements of the embodiments of the present disclosure. The process environment 128 within the process chamber 124, for example, comprises a vacuum produced by a vacuum source 130 (e.g., a vacuum pump) coupled to the process chamber 124 and configured to substantially evacuate the process chamber 124.

The controller 132 is provided for overall control of the vacuum system 100. The controller 132 may include a microprocessor, a microcontroller, or other devices. The controller 132 may be coupled to the components of the system 100 in any suitable manner (e.g., via one or more transmission media, which may include wired and/or wireless transmission media) such that the controller 132 can receive output. The controller 132 may be configured to perform a number of functions using the output. The controller 132 optionally may be in electronic communication with an inspection tool, a metrology tool, a repair tool, or a review tool (not illustrated) to receive additional information or send instructions.

The controller 132 may be part of various systems, including a personal computer system, image computer, mainframe computer system, workstation, network appliance, internet appliance, or other device. The subsystem(s) or system(s) may also include any suitable processor known in the art, such as a parallel processor. In addition, the subsystem(s) or system(s) may include a platform with high-speed processing and software, either as a standalone or a networked tool.

The controller 132 may be disposed in or otherwise part of the system 100 or another device. In an example, the controller 132 may be part of a standalone control unit or in a centralized quality control unit. Multiple controllers 132 may be used, defining multiple subsystems of the system 100.

The controller 132 may be implemented in practice by any combination of hardware, software, and firmware. Also, its functions as described herein may be performed by one unit, or divided up among different components, each of which may be implemented in turn by any combination of hardware, software and firmware. Program code or instructions for the controller 132 to implement various methods and functions may be stored in readable storage media, such as a memory.

If the system 100 includes more than one subsystem, then the different controllers 132 may be coupled to each other such that images, data, information, instructions, etc. can be sent between the subsystems. For example, one subsystem may be coupled to additional subsystem(s) by any suitable transmission media, which may include any suitable wired and/or wireless transmission media known in the art. Two or more of such subsystems may also be effectively coupled by a shared computer-readable storage medium (not shown).

The controller 132 may be configured to perform a number of functions using the output of the system 100 or other output. For instance, the controller 132 may be configured to send the output to an electronic data storage unit or another storage medium. The controller 132 may be further configured as described herein.

The controller 132 may be configured according to any of the embodiments described herein. The controller 132 also may be configured to perform other functions or additional steps using the output of the system 100 or using images or data from other sources. For example, the controller 132 may be in electronic communication with an upstream inspection tool 150. The upstream inspection tool 150 may be an XRD tool that measures the workpiece 120, a tool with a stage and a second camera configured to capture one or more upstream images of the workpiece 120, or another inspection tool.

The controller 132 may be communicatively coupled to any of the various components or sub-systems of system 100 in any manner known in the art. Moreover, the controller 132 may be configured to receive and/or acquire data or information from other systems (e.g., inspection results from an inspection system such as a review tool, a remote database including design data and the like) by a transmission medium that may include wired and/or wireless portions. In this manner, the transmission medium may serve as a data link between the controller 132 and other subsystems of the system 100 or systems external to system 100. Various steps, functions, and/or operations of system 100 and the methods disclosed herein are carried out by one or more of the following: electronic circuits, logic gates, multiplexers, programmable logic devices, ASICs, analog or digital controls/switches, microcontrollers, or computing systems. Program instructions implementing methods such as those described herein may be transmitted over or stored on carrier medium. The carrier medium may include a storage medium such as a read-only memory, a random-access memory, a magnetic or optical disk, a non-volatile memory, a solid-state memory, a magnetic tape, and the like. A carrier medium may include a transmission medium such as a wire, cable, or wireless transmission link. For instance, the various steps described throughout the present disclosure may be carried out by a single controller 132 (or computer subsystem) or, alternatively, multiple controllers 132 (or multiple computer subsystems). Moreover, different sub-systems of the system 100 may include one or more computing or logic systems. Therefore, the above description should not be interpreted as a limitation on the present disclosure but merely an illustration.

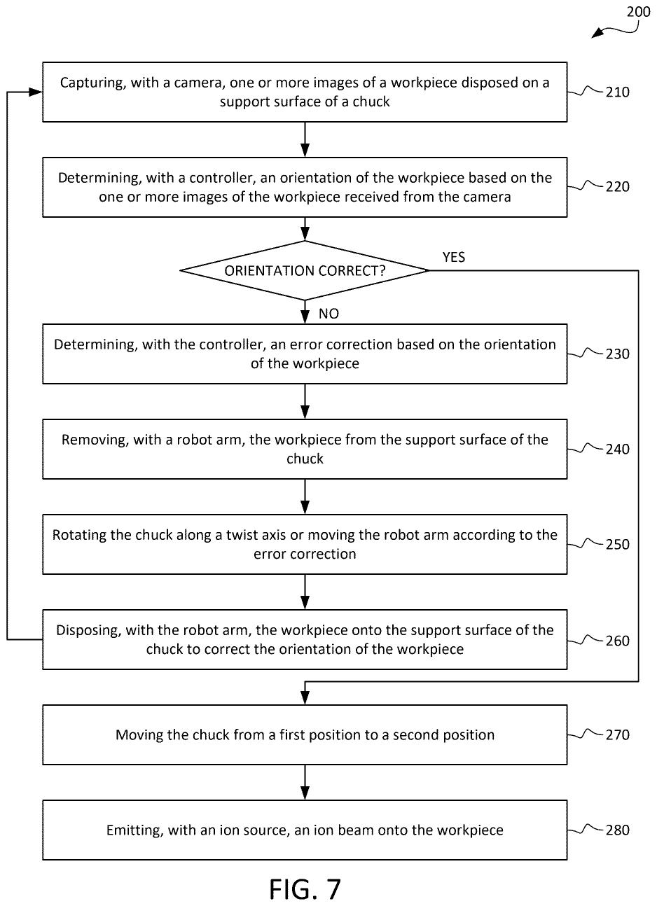

FIG. 7 illustrates an exemplary method 200 that may be implemented by the various systems of the present disclosure. The method 200 may correct the alignment of the wafer prior to ion implantation. The method 200 may comprise the following steps.

At step 210, a camera captures one or more images of a workpiece disposed on a support surface of a chuck. Before step 210, the workpiece may be disposed on the support surface of the chuck by an end effector of a robot arm.

At step 220, a controller determines an orientation of the workpiece based on the one or more images of the workpiece received from the camera. The orientation of the workpiece may include a centering of the workpiece on the support surface of the chuck and/or a twist angle of the workpiece relative to the twist axis of the chuck. If the orientation includes an error, the method 200 may proceed to step 230. If the orientation is correct, the method 200 may proceed to step 270.

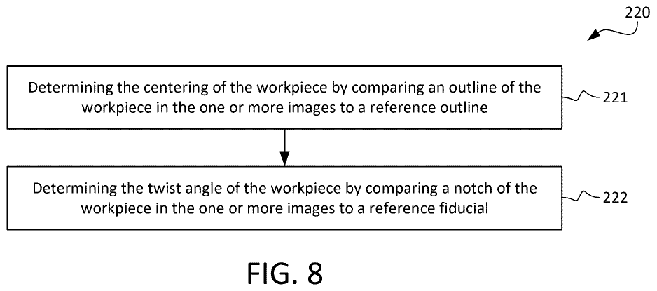

In some embodiments, step 220 may comprise the following steps shown in FIG. 8. At step 221, the controller may determine the centering of the workpiece by comparing an outline of the workpiece in the one or more images to a reference outline. At step 222, the controller may determine the twist angle of the workpiece by comparing a notch or flat of the workpiece in the one or more images to a reference fiducial. The sequence of steps 221 and 222 shown in FIG. 8 is an example only, and the actual sequence and presence of step 221 and/or step 222 in step 220 may depend on the types of error determined to be present in the orientation of the workpiece.

At step 230, the controller determines an error correction based on the orientation of the workpiece. The error correction may include a rotation of the chuck along the twist axis to compensate for the twist angle of the workpiece and/or a movement of the end effector of the robot arm when disposing the workpiece onto the support surface of the chuck to compensate for the centering of the workpiece. In some embodiments, the error correction may include a rotation of the chuck along the twist axis to align the notch or flat of the workpiece with the reference fiducial. Alternatively, the error correction may include a rotation of the chuck along the twist axis to provide the notch or flat of the workpiece at a predetermined angle with the reference fiducial. The predetermined angle may be set based on an earlier inspection of the workpiece. For example, an x-ray diffraction (XRD) tool may be used to determine the crystalline structure and crystalline orientation of the workpiece at an earlier step in the method 200, and a separate camera can be used to capture one or more images of the workpiece while under inspection by the XRD tool in order to determine the twist angle of the workpiece relative to a fiducial marker of the XRD stage. Accordingly, the error correction may rotate the chuck along the twist axis according to the predetermined angle, such that the workpiece is in the same orientation as when inspected by the XRD tool, which can improve alignment of the workpiece for channel implants.

At step 240, a robot arm removes the workpiece from the support surface of the chuck. The robot arm may include an end effector configured to remove the workpiece from the support surface of the chuck.

At step 250, the chuck rotates along a twist axis and/or the robot arm moves the workpiece according to the error correction. For example, the chuck may include a first motor configured to rotate the chuck about the twist axis. The chuck may rotate according to the same twist angle as the determined orientation of the workpiece, so as to match the twist angle of the workpiece when the workpiece is disposed on the chuck.

At step 260, the robot arm disposes the workpiece onto the support surface of the chuck to correct the orientation of the workpiece. For example, the robot arm may compensate for a centering error when disposing the workpiece on the chuck. The chuck may rotate along the twist axis with the workpiece disposed on the support surface to further correct the orientation of the workpiece. For example, the chuck may rotate back to a zero-position of the chuck to correct the orientation of the chuck.

After the workpiece is disposed on the support surface of the chuck, the method 200 may repeat steps 210 and 220 by capturing one or more additional images of the workpiece and determine the orientation of the workpiece based on the one or more additional images to verify that the workpiece is in the correct orientation. If the workpiece is not in the correct orientation (i.e., an error in the orientation still exists), the method 200 may repeat steps 230 to 260. If the workpiece is in the correct orientation, the method 200 may proceed to step 270.

At step 270, the chuck moves from a first position to a second position. The first position may be a load/unload position, in which the robot arm is configured to removably dispose the workpiece onto the chuck, within the field of view of the camera. The second position may be an ion implantation position, in which the support surface of the chuck is aligned with an ion beam for ion implantation. The movement of the chuck from the first position to the second position may include a rotation of a tilt angle, which defines the second position. The tilt angle may be a predefined angle (e.g., 90 degrees) relative to the first position or may be a predetermined angle set during earlier inspection of the workpiece. The tilt angle may be defined such that the surface of the workpiece is orthogonal to the path of the ion beam (which may be parallel to or angled relative to the support surface of the chuck) or at an angle such that the ion beam aligns with the crystalline structure and crystalline orientation of the workpiece.

At step 280, an ion source may emit an ion beam onto the workpiece to perform ion implantation. In some embodiments, the ion beam may perform channel implantation in the workpiece.

Although the present disclosure has been described with respect to one or more particular embodiments, it will be understood that other embodiments of the present disclosure may be made without departing from the scope of the present disclosure. Hence, the present disclosure is deemed limited only by the appended claims and the reasonable interpretation thereof.

What is claimed is:

1. A workpiece processing system, comprising:
a chuck configured to support a workpiece on a support surface, wherein the chuck is configured to rotate about a twist axis, the twist axis being orthogonal to the support surface;
a robot arm having an end effector configured to transport the workpiece to and from the support surface of the chuck, the chuck disposed in a first position;
a camera configured to capture one or more images of the workpiece disposed on the support surface of the chuck in the first position; and
a controller in electronic communication with the camera, the chuck, and the robot arm, wherein the controller is configured to:
receive the one or more images of the workpiece from the camera;
determine an orientation of the workpiece based on the one or more images of the workpiece;
determine an error correction based on the orientation of the workpiece;
send instructions to the robot arm to remove the workpiece from the support surface of the chuck;
send instructions to the chuck to rotate about the twist axis or send instructions to the robot arm to move the workpiece according to the error correction; and
send instructions to the robot arm to dispose the workpiece onto the support surface of the chuck to correct the orientation of the workpiece.

2. The workpiece processing system of claim 1, further comprising:
an ion source configured to emit an ion beam onto the workpiece disposed on the support surface of the chuck in a second position;
wherein the controller is in electronic communication with the ion source, and the controller is further configured to:
send instructions to the chuck to move from the first position to the second position after correcting the orientation of the workpiece; and
send instructions to the ion source to emit the ion beam onto the workpiece.

3. The workpiece processing system of claim 2, wherein the ion beam is configured to perform channel implantation in the workpiece.

4. The workpiece processing system of claim 2, wherein the chuck includes a first motor configured to rotate the chuck along the twist axis and a second motor configured to move the chuck from the first position to the second position.

5. The workpiece processing system of claim 1, wherein the orientation of the workpiece includes a centering of the workpiece on the support surface of the chuck and a twist angle of the workpiece relative to the twist axis of the chuck.

6. The workpiece processing system of claim 5, wherein the error correction includes a rotation of the chuck along the twist axis to compensate for the twist angle of the workpiece.

7. The workpiece processing system of claim 6, wherein the rotation of the chuck along the twist axis compensates for the twist angle of the workpiece by rotating to a predetermined angle set by inspection of the workpiece at an upstream inspection tool.

8. The workpiece processing system of claim 7, wherein the upstream inspection tool is an x-ray diffraction tool, and wherein the upstream inspection tool further includes a stage configured to support the workpiece and a second camera configured to capture one or more upstream images of the workpiece.

9. The workpiece processing system of claim 8, wherein the controller is further configured to:
receive the one or more upstream images of the workpiece; and
determine an orientation of the workpiece in the upstream inspection tool relative to a fiducial marker of the stage.

10. The workpiece processing system of claim 8, wherein the error correction is further based on the orientation of the workpiece in the upstream inspection tool relative to the fiducial marker.

11. The workpiece processing system of claim 5, wherein the error correction includes a movement of the end effector of the robot arm to compensate for the centering of the workpiece.

12. The workpiece processing system of claim 5, wherein the controller is configured to determine the centering of the workpiece by comparing an outline of the workpiece in the one or more images to a reference outline.

13. The workpiece processing system of claim 5, wherein the controller is configured to determine the twist angle of the workpiece by comparing a notch or flat of the workpiece in the one or more images to a reference fiducial.

14. The workpiece processing system of claim 1, wherein the controller is further configured to:
receive one or more images of the workpiece after the robot arm disposes the workpiece onto the support surface of the chuck; and
verify the corrected orientation of the workpiece based on the one or more images of the workpiece.

15. The workpiece processing system of claim 1, wherein the camera is disposed in an ion implanter.

16. A method comprising:
capturing, with a camera, one or more images of a workpiece disposed on a support surface of a chuck;
determining, with a controller, an orientation of the workpiece based on the one or more images of the workpiece received from the camera;
determining, with the controller, an error correction based on the orientation of the workpiece;
removing, with a robot arm, the workpiece from the support surface of the chuck;
rotating the chuck along a twist axis or moving the robot arm according to the error correction; and
disposing, with the robot arm, the workpiece onto the support surface of the chuck to correct the orientation of the workpiece.

17. The method of claim 16, further comprising:
moving the chuck from a first position to a second position, wherein in the first position, the workpiece disposed on the support surface of the chuck is aligned with the camera, and in the second position, the workpiece disposed on the support surface of the chuck is aligned with an ion beam; and
emitting, with an ion source, the ion beam onto the workpiece.

18. The method of claim 17, further comprising performing a channel implantation in the workpiece with the ion beam.

19. The method of claim 16, wherein the orientation of the workpiece includes a centering of the workpiece on the support surface of the chuck and a twist angle of the workpiece relative to the twist axis of the chuck.

20. The method of claim 19, wherein the error correction includes a rotation of the chuck along the twist axis to compensate for the twist angle of the workpiece.

21. The method of claim 20, wherein the rotation of the chuck along the twist axis compensates for the twist angle of the workpiece by rotating to a predetermined angle set by inspection of the workpiece at an upstream inspection tool.

22. The method of claim 21, wherein the upstream inspection tool is an x-ray diffraction tool.

23. The method of claim 19, wherein determining, with the controller, the orientation of the workpiece based on the one or more images of the workpiece received from the camera comprises:
determining the centering of the workpiece by comparing an outline of the workpiece in the one or more images to a reference outline.

24. The method of claim 19, wherein determining, with the controller, the orientation of the workpiece based on the one or more images of the workpiece received from the camera comprises:
determining the twist angle of the workpiece by comparing a notch or flat of the workpiece in the one or more images to a reference fiducial.

25. The method of claim 16, further comprising:
capturing, with the camera, one or more additional images of the workpiece after the robot arm disposes the workpiece onto the support surface of the chuck; and
determining, with the controller, the orientation of the workpiece based on the one or more additional images of the workpiece to verify that the workpiece is in the correct orientation.
